(19) United States
(12) Patent Application Publication
(10) Pub. No.: US 2024/0192040 A1
(43) Pub. Date: Jun. 13, 2024

(54) SEMICONDUCTOR MANUFACTURING CHEMICAL COMPOUND MONITORING PROCESS

(71) Applicant: ASM IP Holding B.V, Almere (NL)

(72) Inventors: Panagiota Arnou, Leuven (BE); Tom Van Kesteren, Bilthoven (NL); Mehmet Orhan Tas, Leuven (BE); Gido Van Der Star, Amersfoort (NL)

(21) Appl. No.: 18/532,190

(22) Filed: Dec. 7, 2023

Related U.S. Application Data
(60) Provisional application No. 63/386,775, filed on Dec. 9, 2022.

(51) Int. Cl. G01F 15/075; C23C 16/455; C23C 16/52

(52) U.S. Cl. CPC G01F 15/0755; C23C 16/45544; C23C 16/52

(57) ABSTRACT

In general the various aspects of the technology of the present disclosure relate to semiconductor processing, and particularly to monitoring the amount of chemicals consumed by a semiconductor manufacturing process.

### CROSS-REFERENCE TO RELATED APPLICATION(S)

This application claims the benefit of U.S. Provisional Application 63/386,775 filed on Dec. 9, 2022, the entire contents of which are incorporated herein by reference.

### FIELD

In general the various aspects of the technology of the present disclosure relate to semiconductor processing, and particularly to monitoring the amount of chemicals consumed by a semiconductor manufacturing process.

### BACKGROUND

With semiconductors and semiconductor manufacturing processes becoming more advanced, there is a need for greater uniformity and process control during the manufacturing process.

During processes such as Atomic Layer Deposition (ALD), Epitaxy, Plasma-enhanced chemical vapor deposition (PECVD), Plasma-enhanced atomic layer deposition (PEALD), Oxidation, curing, diffusion (annealing) and Chemical Vapor Deposition (CVD) precursors and other chemical compounds which may be in the form of a gas, liquid or solid are deposited onto or contacted with a workpiece. These chemical compounds are often stored in container or storage vessel from where they are transported to the workpiece in the reaction chamber.

While the process is being performed, it may be advantageous to monitor the actual amount of chemical components consumed in order to prevent manufacturing defects due to exhaustion of the chemical components. The ability to monitor the actual consumption is important because it ensures process quality, allows efficient scheduling of storage vessel changes, maximizes use of expensive chemistry, and improves inventory management.

Often the exact amount of chemical compounds used in the reaction chamber is closely monitored because small deviations therein may result in large quality differences during the actual reactions. However, in order to accurately control the amount of chemical compounds introduced in the reaction chamber often the chemical compounds are introduced into the reaction chamber once a steady flow of chemical compounds is reached. Indeed, once a chemical compound start flowing from the storage container to the reaction or process chamber the profile can be divided into three phases, (1) an attack or initiation phase corresponding to the start of chemical flowing through the process line, building up its concentration until a steady state is reached, (2) a sustain phase corresponding to the point in time in which the chemical flow has reached a steady state and the concentration of the chemical remains constant, and (3) a release phase corresponding to the point in time where the concentration of the chemical reduces from its steady state. Often, during the semiconductor manufacturing processes only the sustain phase is guided to the process chamber because of the steady state delivery of chemical compounds to the reaction chamber. During the other phases often the chemicals are vented towards systems that preferably allow the recuperation of the chemical compounds. A result of the venting is that often the actual amounts of chemical compounds used in the semiconductor manufacturing processes do not match with the actual amounts of chemical compounds that are consumed by the processes.

Therefore, a need exists for an improved method and apparatus for monitoring the amount of chemical compounds that are consumed during semiconductor manufacturing processes.

### SUMMARY

A first overview of various aspects of the technology of the present disclosure is given herein, after which specific embodiments will be described in more detail. This overview is meant to aid the reader in understanding the technological concepts more quickly, but it is not meant to identify the most important or essential features thereof, nor is it meant to limit the scope of the present disclosure, which is limited only by the claims.

An aspect of the present disclosure is a method for monitoring consumption of chemical compounds in a semiconductor manufacturing process, the method comprising the steps of:
measuring the flow of a chemical compound through a process line fluidically connecting a storage vessel for said chemical compound to a process chamber; and
determining from said measurement the amount of said chemical compound consumed by said semiconductor manufacturing process.

More in particular, the method as disclosed herein provides that said determining step comprises calculating the consumption of said chemical compound based on said measurement of the chemical compound flow through a process line over time.

More in particular, the method according to the present disclosure provides that said measuring step at least comprises
determining the open/closed status of a process line valve on said process line; and
measuring the time said process line valve has an open status;
   wherein said amount of chemical compound consumed by said semiconductor manufacturing process is calculated by integrating the flow rate of said chemical compound through said process line over the time said process line valve has an open status.

More in particular, the method according to the present disclosure provides that said flow rate of said chemical compound through said process line is set by a flow controller (FC), such as a mass flow controller (MFC) or a liquid flow controller (LFC), positioned on said process line.

More in particular, the method according to the present disclosure provides that the method determines:
the total chemical compound consumption of said semiconductor manufacturing process; and/or;
the partial chemical compound consumption of sub-steps of said semiconductor manufacturing process.

More in particular, the method according to the present disclosure provides that the method further comprises the step of providing a warning and/or alarm once the total chemical compound consumption of said semiconductor manufacturing process exceeds a set threshold level.

More in particular, the method according to the present disclosure provides that the chemical compound is a precursor. More in particular, said precursor is a liquid or a solid precursor.

More in particular, the method according to the present disclosure provides that said precursor is a liquid or solid precursor comprising a metal or a metalloid. More particularly, said metal is selected from an alkaline metal, an alkaline earth metal, a transition metal, and a rare earth metal.

More in particular, the method according to the present disclosure provides that said liquid or solid precursor comprises one or more ligands, the one or more ligands being selected from H, halogens, alkyls, alkenyls, alkynes, carbonyls, dienyls, beta-diketonates, substituted or unsubstituted cyclodienyls, and substituted or unsubstituted aryls.

More in particular, the method according to the present disclosure provides that said liquid or solid precursor is homoleptic or heteroleptic.

More in particular, the method according to the present disclosure provides that said liquid or solid precursor comprises a metal-carbon bond.

More in particular, the method according to the present disclosure provides that said liquid or solid precursor comprises a pi complex.

In a further aspect, the present disclosure provides in a method performed by one or more computers for monitoring the consumption of chemical compounds in a semiconductor manufacturing process, comprising the steps of:
receiving data related to flow of a chemical compound through a process line fluidically connecting a storage vessel to a process chamber; and
determining, from said data, the amount of said chemical compound consumed by the semiconductor manufacturing process.

Another aspect of the present disclosure relates to a semiconductor manufacturing system comprising a controller configured to perform the method as disclosed herein.

Another aspect of the present disclosure relates to a semiconductor manufacturing system comprising
at least one chemical compound flow sensor configured for the real-time monitoring and detection of chemical compound flow through a process line; and
a controller configured to receive chemical compound flow data from the chemical compound flow sensor and determine, from said data, the amount of chemical compound consumed by said semiconductor manufacturing process.

Another aspect of the present disclosure relates to a system for monitoring the consumption of chemical compounds in a semiconductor manufacturing process comprising a controller configured to receive data related to the chemical compound flow through a process line fluidically connecting a storage vessel to a process chamber and determine, from said data, the amount of chemical compound consumed by the semiconductor manufacturing process.

More in particular, the semiconductor manufacturing system or system for monitoring the consumption of chemical compounds in a semiconductor manufacturing process according to the present disclosure provides that the system comprises at least one sensor for the real-time monitoring and detection of the flow of a chemical compound through a process line. More in particular, said system comprises at least one sensor for the real-time monitoring and detection of the open/closed status of a process line valve on said process line.

More in particular, the semiconductor manufacturing system or system for monitoring the consumption of chemical compounds in a semiconductor manufacturing process according to the present disclosure provides that the process line comprises a manifold valve towards said process chamber and a manifold valve towards a vent outlet.

More in particular, the semiconductor manufacturing system or system for monitoring the consumption of chemical compounds in a semiconductor manufacturing process according to the present disclosure provides that the system comprises one or more storage vessels connected with one or more process chambers.

More in particular, the semiconductor manufacturing system or system for monitoring the consumption of chemical compounds in a semiconductor manufacturing process according to the present disclosure provides that the chemical compound is a precursor.

Another aspect of the present disclosure relates to one or more non-transitory computer readable media encoded with a computer program, the computer program comprising instructions that, when executed by one or more computers, cause the one or more computers to perform operations for determining the amount of chemical compound consumed by a semiconductor manufacturing process when provided with data related to the flow of said chemical compound through a process line fluidically connecting a storage vessel to a process chamber as input.

Another aspect of the present disclosure relates to a computer program product for implementing, when executed on a controller, a method for monitoring consumption of chemical compounds in a semiconductor manufacturing process as disclosed herein when provided with data from the measurement of the flow of a chemical compound through said process line as input.

### BRIEF DESCRIPTION OF THE DRAWINGS

The following description of the figures relate to specific embodiments of the disclosure which are merely exemplary in nature and not intended to limit the present teachings, their application or uses.

FIG. 1 schematically shows a storage vessel for chemical compounds connected to a process chamber where the consumption of the chemical compound in the semiconductor manufacturing process is monitored.

FIG. 2 schematically shows a multitude of storage vessels for chemical compounds connected to a process chamber where the consumption of the chemical compounds in the semiconductor manufacturing process is monitored.

### DETAILED DESCRIPTION

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” said recited members, elements or method steps. The singular forms “a”, “an”, and “the” include both singular and plural referents unless the context clearly dictates otherwise.

As used herein, relative terms, such as “left,” “right,” “front,” “back,” “top,” “bottom,” “over,” “under,” etc., are used for descriptive purposes and not necessarily for describing permanent relative positions. It is to be understood that such terms are interchangeable under appropriate circumstances and that the embodiment as described herein are capable of operation in other orientations than those illustrated or described herein unless the context clearly dictates otherwise.

Objects described herein as being “adjacent” to each other reflect a functional relationship between the described objects, that is, the term indicates the described objects must be adjacent in a way to perform a designated function which may be a direct (i.e. physical) or indirect (i.e. close to or near) contact, as appropriate for the context in which the phrase is used.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” said value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all numbers and fractions subsumed within the respective ranges, as well as the recited endpoints. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

An overview of various aspects of the technology of the present disclosure is given hereinbelow, after which specific embodiments will be described in more detail. This overview is meant to aid the reader in understanding the technological concepts more quickly, but it is not meant to identify the most important or essential features thereof, nor is it meant to limit the scope of the present disclosure, which is limited only by the claims. When describing specific embodiments, reference is made to the accompanying drawings, which are provided solely to aid in the understanding of the described embodiment.

Disclosed herein are methods and systems for determining the actual consumed amount of chemical compounds that are used in a semiconductor manufacturing process. Typically, the actual consumed amount of chemical compounds used in a semiconductor manufacturing process does not match with the amount of chemical compounds that are introduced in the reaction chamber of the semiconductor manufacturing process. Often considerable amount of chemical compounds is lost by side processes such as for instance the venting of the chemical compounds. In addition, not all chemical compounds consumed by the semiconductor manufacturing process are actually introduced in the reaction chamber of the semiconductor manufacturing process (e.g. chemical compounds that are used to flush the process lines). It is also of importance to keep track of the consumption of these chemical compounds. The methods and systems as disclosed herein provide in the measurement and determination of the actual consumed amount of chemical compounds used by the entire semiconductor manufacturing process.

An aspect of the present disclosure is a method for monitoring consumption of chemical compounds in a semiconductor manufacturing process, the method comprising the steps of:
measuring the flow of a chemical compound through a process line fluidically connecting a storage vessel for said chemical compound to a process chamber; and
determining from said measurement the amount of said chemical compound consumed by said semiconductor manufacturing process.

As referred to herein, the term “chemical compound” refers to the chemical compounds used in semiconductor manufacturing techniques such as Chemical Vapor Deposition (CVD), Atomic Layer Deposition (ALD), Plasma-enhanced chemical vapor deposition (PECVD), diffusion (annealing) and epitaxy. The chemical compounds may be chosen based on the particular process to be performed in the process chamber. The chemical compounds may be in gaseous, liquid or solid form and may for instance be reactants such as precursors, carrier gasses such as ammonia and inert gasses and others. The carrier gas may comprise N₂, and noble gases such as for example, Ar, Ne, He, Xe and Kr. In some embodiments, the carrier gas may comprise substantially N₂, Ar, He, or combinations thereof.

As referred to herein, the term “process chamber” or “reactor chamber” refers to the reaction chamber that is coupled to a chemical compound delivery system. The process chamber may include an inner volume with a substrate support disposed therein for supporting a substrate to be processed (such as a semiconductor wafer or the like). The process chamber may be configured for ALD, CVD, or the like. The process chamber may further comprise a processing system comprising additional components, for example, one or more radio-frequency or other energy sources for generating a plasma within the inner volume or for providing radio-frequency bias to a substrate disposed on the substrate support.

As referred to herein, the term “storage vessel” refers to the chamber that is coupled to the process chamber and comprises chemical compounds. A “process line” connects the storage vessel to the process chamber and therefore conduits the chemical compounds from their respective storage vessel to the process chamber.

By measuring the flow of the chemical compounds through the process line the actual consumed amount of chemical compounds used in the semiconductor manufacturing process can be determined. This allows for consumption tracking for all chemicals used. The amount consumed is a property value that can be reported and used to notify the users of the semiconductor manufacturing process at an early stage if one or more of the chemical compounds is running low. This way problems with the semiconductor manufacturing process caused by the depletion of one or more of the chemical compounds can be avoided.

The determination of the amount of chemical compound consumed by the semiconductor manufacturing process from the measurements is typically calculated from the actual flow rate for the entire time that the process line valve is open. This means that it will be independent from the manifold state of the reactor valves. A correct monitoring of the actual consumed amount of chemical compounds used in the semiconductor manufacturing process allows for a better planning of preventive maintenance (such as storage vessel replacement). It also allows for feedback in terms of chemical compound usage, which allows for consumption optimization and cost reduction.

More in particular, the method as disclosed herein provides that said determining step comprises calculating the consumption of said chemical compound based on said measurement of the chemical compound flow through a process line over time.

More in particular, the method according to the present disclosure provides that said measuring step at least comprises
determining the open/closed status of a process line valve on said process line; and
measuring the time said process line valve has an open status;
   wherein said amount of chemical compound consumed by said semiconductor manufacturing process is calculated by integrating the flow rate of said chemical compound through said process line over the time said process line valve has an open status.

As used herein the term “process line valve” refers to the valve that controls the flow of chemical compounds from their storage container to the process chamber. The process line valve is positioned in proximity of the storage container, in particular downstream from the storage container on a yet unbranched part of the process line. Indeed, while the process line may be branched between the storage container and the process chamber (e.g. a branch to a venting system), the process line valve is positioned in proximity of the storage container downstream from the storage container on an unbranched part of the process line.

The flow rate of said chemical compound through said process line can be measured using flow meters, such as a mass flow meter (MFM) or a liquid flow meter (LFM), positioned on said process line. The flow meter determines the flow rate of the chemical compound through the process line and in the method as disclosed herein this value is used to calculate the actual amount of chemical compound consumed by the semiconductor manufacturing process.

More in particular, the method according to the present disclosure provides that said flow rate of said chemical compound through said process line is set by a flow controller (FC), such as a mass flow controller (MFC) or a liquid flow controller (LFC), positioned on said process line.

By determining the time the process line valve is in an open configuration the actual consumed amount of chemical compound can be determined either by using the fixed flow rate through the process line, or by using a flow controller (FC), such as a mass flow controller (MFC) or a liquid flow controller (LFC), positioned on said process line. The flow controller (FC) on the process line allows for the accurate regulation of the flow rate through the process line.

In a particular embodiment the calculation of the actual consumed amount of chemical compound also includes measuring and including a residual flow of the chemical compounds through the flow controller. Indeed, once the process line valve is switched to a closed position a residual flow of chemical compounds may still pass through the flow controller. While the residual flow may be limited, it may be relevant in the method and systems as disclosed herein to also add the residual flow amount to the calculation.

More in particular, the method according to the present disclosure provides that the method determines:
the total chemical compound consumption of said semiconductor manufacturing process; and/or;
the partial chemical compound consumption of sub-steps of said semiconductor manufacturing process.

The methods and systems as disclosed herein allow for the accurate tracking of either or both of the total chemical compound consumption over the entire semiconductor manufacturing process and/or the partial chemical compound consumption of certain sub-steps of the semiconductor manufacturing process thereby allowing comparisons between different recipes/jobs and optimization of the chemical compound consumption. Typically a counter will log the total consumption of each chemical compound in the system, a counter that can be reset by the user when for instance a storage vessel is replaced. Also, logging the sub-steps of the processes allows for further optimization and waste reduction.

More in particular, the method according to the present disclosure provides that the method further comprises the step of providing a warning and/or alarm once the total chemical compound consumption of said semiconductor manufacturing process exceeds a set threshold level. In general, a warning and/or is provided when the consumption of the semiconductor manufacturing process exceeds a set threshold. The threshold can be set by a user. Also, certain threshold can be set to detect malfunctions of the system, thereby allowing early warning systems to intervene in time, preferably avoiding wafer scrap and the scheduling of preventive maintenance.

The total chemical compound consumption of said semiconductor manufacturing process as used herein can be a value or counter that measures the total chemical compound consumption over the entire lifetime of the semiconductor manufacturing process and/or a value or counter that measures the total chemical compound consumption since the last replacement of the storage container of said chemical compound. Additionally or alternatively the value or counter is a reverse count or backwards count to more clearly indicate when the chemical compound storage container will be depleted.

More in particular, the method according to the present disclosure provides that the chemical compound is a precursor. More in particular, said precursor is a liquid or a solid precursor. During the typical semiconductor manufacturing process the substrate undergoes a plurality of deposition cycles which typically comprise a precursor pulse and a reactant pulse. After a pre-determined amount of deposition cycles, the method ends. During such a precursor pulse liquid or solid precursor is transported from the precursor vessel (storage vessel) to the process chamber. For solid precursors this is done by flowing a carrier gas through the precursor vessel, thereby generating a process gas comprising the carrier gas and vaporized solid precursor which is subsequently provided to the process chamber. This typically occurs in a pulse train where at specified time intervals transport of the liquid or solid precursor from the precursor vessel to the process chamber occurs. A single precursor pulse can comprise three phases: (1) an attack or initiation phase corresponding to the start of precursor flowing through the process line, building up its concentration until a steady state is reached, (2) a sustain phase corresponding to the point in time in which the precursor flow has reached a steady state and the concentration of the precursor remains the same, and (3) a release phase corresponding to the point in time where the concentration of the precursor reduces from its steady state. For the semiconductor manufacturing process especially a flow in the sustain phase let into the process chamber, the flow of the attack phase and the release phase are redirected to for instance a vent. Also, to allow purging of the process lines and/or the process chamber, a purge valve may be used on a purge line. The purging can be conducted with inert gas in between precursor pulses in order to clean the process chamber and remove any precursor that is unattached to the surface after that particular pulse. The consumption of the purge gas can also be tracked using the method and systems as disclosed herein.

In particular, in the methods and systems according to the present disclosure the precursor is a solid precursor comprising a metal or a metalloid. More particularly, said metal is selected from an alkaline metal, an alkaline earth metal, a transition metal, a rare earth metal or a combination thereof. More particularly, said metalloid, an element that has properties that are intermediate between those of metals and nonmetals, is silicon, boron, germanium, arsenic, antimony and/or tellurium. The solid precursor may also comprise one or more ligands, the one or more ligands being selected from H, halogens, alkyls, alkenyls, alkynes, carbonyls, dienyls, beta-diketonates, substituted or unsubstituted cyclodienyls, substituted or unsubstituted aryls or a combination thereof. Suitable halogens include F, Br, Cl, and/or I. Suitable alkyls, alkenyls, alkynes, dienyls, and cyclodienyls are typically C1 to C8 compounds. Suitable substituents on the cyclodienyls and aryls include C1 to C3 alkyls. Suitable beta-diketonates include 1,1,1,5,5,5-hexafluoropentane-2,4-dionate (hfac) and/or 2,4-pentanedione (hacac). In particular embodiments the solid precursor is a homoleptic chemical compound (a metal compound where all ligands are identical) or a heteroleptic chemical compound (a metal compound having two or more different types of ligand). In further particular embodiments the solid precursor comprises a metal-carbon bond. In further particular embodiments the solid precursor comprises a pi complex. An exemplary solid precursor is HfCl₄.

In the calculation of the consumption of solid precursor other factors such as the inlet gases in the solid precursor vessel (e.g. carrier gas and the gas determining the pressure of the precursor) are taken into account in addition to the flow rate in the process line. To account therefore typically a conversion factor, defined by the user, could be used.

In particular, in the methods and systems according to the present disclosure the precursor is a liquid precursor comprising a metal, more particularly, said metal is selected from an alkaline metal, an alkaline earth metal, a transition metal, a rare earth metal or a combination thereof. The liquid precursor may also comprise one or more ligands, the one or more ligands being selected from H, halogens, alkyls, alkenyls, alkynes, carbonyls, dienyls, beta-diketonates, substituted or unsubstituted cyclodienyls, substituted or unsubstituted aryls or a combination thereof. Suitable halogens include F, Br, Cl, and/or I. In particular embodiments the liquid precursor is a homoleptic chemical compound (a metal compound where all ligands are identical) or a heteroleptic chemical compound (a metal compound having two or more different types of ligand). In further particular embodiments the liquid precursor comprises a metal-carbon bond. In further particular embodiments the liquid precursor comprises a pi complex. Exemplary liquid precursors are Trimethylaluminum (TMA), tetrakis-ethylmethylaminohafnium (TEMAHf), octa chlorotrisilane (OCTS), N,N,N′,N′-tetraethylsilanediamine (SAM24), Trichlorosilane, Dichlorosilane, Tetraethylorthosilicate (TEOS), Trimethylborate (TMB), Trichloroethane, Boron tribrornide, Phosphorous oxychloride, Fluorotriethoxysilane (FTES), Tetrakis-dimethylamino Titanium (TDMAT), Tetrakis-diethylamino (TDEAT), CuTMVS, Trimethylcyclotetrasiloxane (TOMCATS), Diethylsilane, Triethylborate (TEB), Trimethyl Phosphite (TMPI), TitaniumChloride TiCl₄, Trisilane Si₃H₈ and Triethylphosphate (TEPO), Molybdenum pentachloride MoCl₅, Molybdenumdioxi dichloride MoO₂Cl₂.

In a further aspect, the present disclosure provides in a method performed by one or more computers for monitoring the consumption of chemical compounds in a semiconductor manufacturing process, comprising the steps of:
receiving data related to flow of a chemical compound through a process line fluidically connecting a storage vessel to a process chamber; and
determining, from said data, the amount of said chemical compound consumed by the semiconductor manufacturing process.

Another aspect of the present disclosure relates to a semiconductor manufacturing system comprising a controller configured to perform the method as disclosed herein.

Another aspect of the present disclosure relates to a semiconductor manufacturing system comprising
at least one chemical compound flow sensor configured for the real-time monitoring and detection of chemical compound flow through a process line; and
a controller configured to receive chemical compound flow data from the chemical compound flow sensor and determine, from said data, the amount of chemical compound consumed by said semiconductor manufacturing process.

Another aspect of the present disclosure relates to a system for monitoring the consumption of chemical compounds in a semiconductor manufacturing process comprising a controller configured to receive data related to the chemical compound flow through a process line fluidically connecting a storage vessel to a process chamber and determine, from said data, the amount of chemical compound consumed by the semiconductor manufacturing process.

More in particular, the system as disclosed herein provides that said controller is further configured to determine the time remaining before the storage vessel is depleted and/or requires refilling.

More in particular, the system as disclosed herein provides that said controller is configured to communicate the amount of chemical remaining in said storage vessel and/or the actual consumed amount of chemical to a further system controller.

More in particular, the system according to the present disclosure provides that said controller or said system controller is configured to display the amount of chemical compound remaining in each storage vessel and/or the actual consumed amount of each chemical compound on a graphical user interface (GUI), wherein said controller or said system controller is further configured to generate a warning/alarm message on said GUI when said the storage vessel is nearly depleted.

A “controller” may be coupled to various components of the processing system for controlling the operation thereof. The controller generally comprises a central processing unit (CPU), a memory, and support circuits for the CPU. The controller may control the processing system directly, or via computers (or controllers) associated with particular process chamber and/or the support system components. The controller may be one of any form of general-purpose computer processor that can be used in an industrial setting for controlling various chambers and sub-processors. The memory, or computer-readable medium of the CPU may be one or more of readily available memory such as random-access memory (RAM), NAND memory, read only memory (ROM), floppy disk, hard disk, flash, or any other form of digital storage, local or remote. The support circuits are coupled to the CPU for supporting the processor in a conventional manner. These circuits include cache, power supplies, clock circuits, input/output circuitry and subsystems, and the like. Inventive methods as described herein may be stored in the memory as software routine that may be executed or invoked to control the operation of the processing system in the manner described herein. The software routine may also be stored and/or executed by a second CPU that is remotely located from the hardware being controlled by the CPU.

More in particular, the semiconductor manufacturing system or system for monitoring the consumption of chemical compounds in a semiconductor manufacturing process according to the present disclosure provides that the system comprises at least one sensor for the real-time monitoring and detection of the flow of a chemical compound through a process line. More in particular, said system comprises at least one sensor for the real-time monitoring and detection of the open/closed status of a process line valve on said process line.

More in particular, the semiconductor manufacturing system or system for monitoring the consumption of chemical compounds in a semiconductor manufacturing process according to the present disclosure provides that the process line comprises a manifold valve towards said process chamber and a manifold valve towards a vent outlet.

More in particular, the semiconductor manufacturing system or system for monitoring the consumption of chemical compounds in a semiconductor manufacturing process according to the present disclosure provides that the system comprises one or more storage vessels connected with one or more process chambers.

Indeed, the methods and systems as described herein can be used to monitor the consumption of several of the chemical compounds that are used in the semiconductor manufacturing process. Preferably the process line for each of the chemical compounds run parallel to each other although depending on the manufacturing process and the types of chemicals used, some of these process lines can be combined with each other.

More in particular, the semiconductor manufacturing system or system for monitoring the consumption of chemical compounds in a semiconductor manufacturing process according to the present disclosure provides that the chemical compound is a precursor.

Another aspect of the present disclosure relates to one or more non-transitory computer readable media encoded with a computer program, the computer program comprising instructions that, when executed by one or more computers, cause the one or more computers to perform operations for determining the amount of chemical compound consumed by a semiconductor manufacturing process when provided with data related to the flow of said chemical compound through a process line fluidically connecting a storage vessel to a process chamber as input.

Another aspect of the present disclosure relates to a computer program product for implementing, when executed on a controller, a method for monitoring consumption of chemical compounds in a semiconductor manufacturing process as disclosed herein when provided with data from the measurement of the flow of a chemical compound through said process line as input.

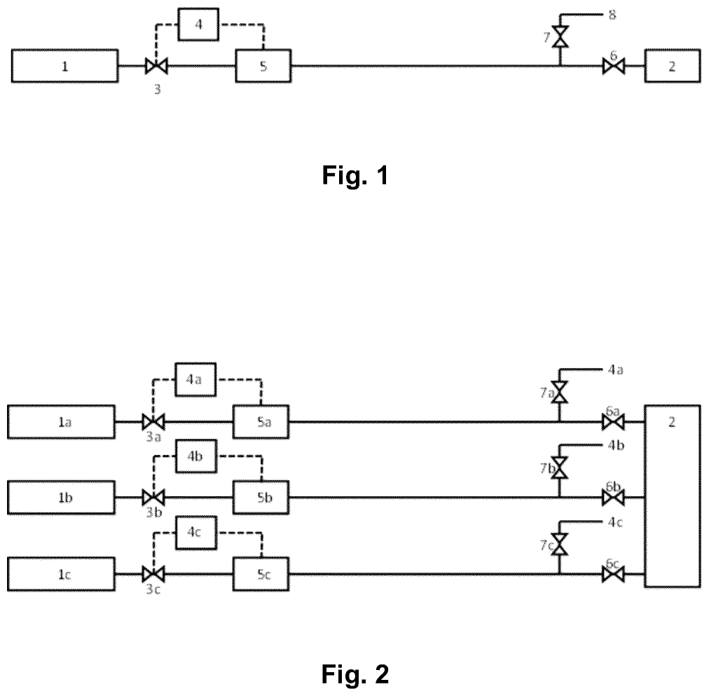

An exemplary system as described herein is shown in FIG. 1. FIG. 1 illustrates a system in accordance with yet additional exemplary embodiments of the disclosure. The system can be used to perform a method as described herein and/or form a structure or device portion as described herein. In the illustrated example of an ALD system (similar configurations can be applied on other semiconductor manufacturing systems), the system includes a storage vessel (1) fluidically connected to a process chamber (2) through a process line. The flow rate through the process line is controlled by a flow controller (5). Near the process chamber (2) the process line splits into two branches, the first branch leading to the process chamber (2) and the second branch leading to the vent outlet (8). The flow through both branches is controlled by manifold valves (6,7) on each of the branches. Near the storage vessel (1) a process line valve (3) controls the flow of chemicals leaving the storage vessel (1). A controller (4) is used to measure the actual amount of chemical components being consumed by the semiconductor manufacturing process.

FIG. 2 shows a system similar to FIG. 1, with the exception that in this figure the consumption of several chemical compounds is determined.

It is noted that FIGS. 1 and 2 in particular pertain to ALD type systems. Similar configurations can be applied on other semiconductor manufacturing systems comprising different apparatuses suitable for other types of semiconductor processing. Differences in the layout and the distribution of valves may be present depending on the process to be carried out. For instance, sometimes only a single inlet line is used but it branches to several FCs placed in parallel or being directed to another part of the semiconductor process.

Also, to allow purging of the process lines and/or the process chamber, a purge valve may be used on a purge line. the purging can be conducted with inert gas. In an ALD process typically after each precursor pulse step there is a purge step, which is used to clean the process chamber and remove any precursor that is unattached to the surface after that particular pulse.

1. A semiconductor manufacturing system comprising:
chemical compound flow sensor for measuring the flow of a chemical compound through a process line fluidically connecting a storage vessel for said chemical compound to a process chamber; and
a controller configured to monitor the consumption of one or more chemical compounds in said semiconductor manufacturing system, said controller being configured to receive chemical compound flow data from said chemical compound flow sensor and determine, from said data, the amount of chemical compound consumed by said semiconductor manufacturing system.

2. The semiconductor manufacturing system according to claim 1, wherein said chemical compound flow sensor is configured for the real-time monitoring and detection of chemical compound flow through said process line.

3. The semiconductor manufacturing system according to claim 2, wherein said system comprises at least one sensor for the real-time monitoring and detection of the open/closed status of a process line valve on said process line.

4. The semiconductor manufacturing system according to claim 3, wherein said chemical compound flow sensor measures the flow of chemical compound through the process line by:
determining the open/closed status of said process line valve on said process line; and
measuring the time said process line valve has an open status; and
wherein the chemical compound consumption is calculated by integrating the flow rate of said chemical compound through said process line over the time said process line valve has an open status.

5. The semiconductor manufacturing system according to claim 4, wherein said flow rate of said chemical compound through said process line is set by a flow controller (FC), such as a mass flow controller (MFC) or a liquid flow controller (LFC), positioned on said process line.

6. The semiconductor manufacturing system according to claim 5, wherein said controller is configured to determine:
the total chemical compound consumption of said semiconductor manufacturing system; and/or;
the partial chemical compound consumption of said semiconductor manufacturing system.

7. The semiconductor manufacturing system according to claim 6, wherein said controller is configured to provide a warning and/or alarm once the total chemical compound consumption of said semiconductor manufacturing system exceeds a set threshold level.

8. The semiconductor manufacturing system according to claim 1, wherein said process line comprises a manifold valve towards said process chamber and a manifold valve towards a vent outlet.

9. The semiconductor manufacturing system according to claim 1, wherein said system comprises one or more storage vessels connected with one or more process chambers.

10. The semiconductor manufacturing system according to claim 1, wherein said chemical compound is a precursor.

11. The semiconductor manufacturing system according to claim 10, wherein said precursor is a liquid or a solid precursor.

12. The semiconductor manufacturing system according to claim 10, wherein said precursor is a liquid or solid precursor comprising a metal or a metalloid.

13. The semiconductor manufacturing system according to claim 12, wherein said metal is selected from an alkaline metal, an alkaline earth metal, a transition metal, and a rare earth metal.

14. The semiconductor manufacturing system according to claim 11, wherein said liquid or solid precursor comprises one or more ligands, the one or more ligands being selected from H, halogens, alkyls, alkenyls, alkynes, carbonyls, dienyls, beta-diketonates, substituted or unsubstituted cyclodienyls, and substituted or unsubstituted aryls.

15. The semiconductor manufacturing system according to claim 11, wherein said liquid or solid precursor is homoleptic.

16. The semiconductor manufacturing system according to claim 11, wherein said liquid or solid precursor is heteroleptic.

17. The semiconductor manufacturing system according to claim 11, wherein said liquid or solid precursor comprises a metal-carbon bond.

18. The semiconductor manufacturing system according to claim 11, wherein said liquid or solid precursor comprises a pi complex.

19. A method for monitoring consumption of chemical compounds in a semiconductor manufacturing process, the method comprising the steps of:
measuring the flow of a chemical compound through a process line fluidically connecting a storage vessel for said chemical compound to a process chamber; and
determining from said measurement the amount of said chemical compound consumed by said semiconductor manufacturing process.

20. A method performed by one or more computers for monitoring the consumption of chemical compounds in a semiconductor manufacturing process, comprising the steps of:
receiving data related to flow of a chemical compound through a process line fluidically connecting a storage vessel to a process chamber; and
determining, from said data, the amount of said chemical compound consumed by the semiconductor manufacturing process.

21. A system for monitoring the consumption of chemical compounds in a semiconductor manufacturing process comprising a controller configured to receive data related to the chemical compound flow through a process line fluidically connecting a storage vessel to a process chamber and determine, from said data, the amount of chemical compound consumed by the semiconductor manufacturing process.

22. One or more non-transitory computer readable media encoded with a computer program, the computer program comprising instructions that, when executed by one or more computers, cause the one or more computers to perform operations for determining the amount of chemical compound consumed by a semiconductor manufacturing process when provided with data related to the flow of said chemical compound through a process line fluidically connecting a storage vessel to a process chamber as input.
